(19) United States
(12) Patent Application Publication
(10) Pub. No.: US 2008/0068228 A1
(43) Pub. Date: Mar. 20, 2008

(54) MOBILE TERMINAL INCLUDING MULTIFUNCTIONAL KEYPAD

(76) Inventor: Yang Jae JEONG, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/856,435

(22) Filed: Sep. 17, 2007

(30) Foreign Application Priority Data
Sep. 20, 2006 (KR) 10-2006-0091138

(51) Int. Cl. H03K 17/94; H03M 11/00

(52) U.S. Cl. 341/28

(57) ABSTRACT

Provided is a mobile terminal including an attachable/detachable keypad which has keys arranged so that a user inputs characters using several fingers of one hand. The mobile terminal includes a keypad. The keypad includes a character part including a consonant part for inputting consonants of Korean alphabet, a right-side vowel part for inputting right-side vowels of Korean alphabet, a bottom vowel part for inputting bottom vowels of Korean alphabet, and a function control part, wherein the same character keys of a first character part having the consonant part located at an upper left portion of the keypad and a second character part having the consonant part located at an upper right portion share the same switch.

### CROSS-REFERENCE TO RELATED APPLICATION

This application claims priority to and the benefit of Korean Patent Application No. 2006-0091138, filed Sep. 20, 2006, the disclosure of which is incorporated herein by reference in its entirety.

### BACKGROUND

1. Field of the Invention

The present invention relates to a mobile terminal, and more particularly, to a mobile terminal including an attachable/detachable keypad which has keys arranged so that a user can input text using several fingers of one hand.

2. Discussion of Related Art

Recently, a mobile terminal serves not only as a simple telephone, but also as a personal digital assistant (PDA), a notebook computer, and so on. The mobile terminal also serves as an intelligent entertainment device. Hence, in order to use a high-performance mobile terminal, a user must input large amounts of various data, quickly and precisely. An existing figure-based input system comprised of 12 keys in 3 columns and 4 rows, however, cannot satisfy such a demand. Thus, there is a need for a new character-based input system.

FIG. 1 illustrates the layout of a Korean alphabet keypad for a conventional mobile terminal.

Referring to FIG. 1, the keypad includes a vowel part 10 located at an upper portion of the keypad for generating vowels of Korean alphabet, and a consonant part 12 located at a lower portion thereof for generating consonants of Korean alphabet.

The consonant part 12 includes one-stroke consonants of Korean alphabet [symbol] two-stroke consonants of Korean alphabet [symbol] and three-stroke consonants of Korean alphabet

[symbol]

The vowel part 10 is based upon a so-called CheonJiIn system using three basic vowels of Korean alphabet [symbol] which are combined to generate vowels of Korean alphabet. For example, [symbol] is generated when [symbol] and “•” are pressed successively, and “ [symbol] ” is generated when “•” is pressed twice successively and then [symbol] is pressed twice successively. In this manner, all the vowels of Korean alphabet excluding [symbol] and [symbol] are generated in at least two strokes.

In the example of the conventional Korean alphabet keypad layout system as shown in FIG. 1, text input speed is reduced by the number of strokes needed to generate the vowels of Korean alphabet.

The arrangement of the consonants and vowels of Korean alphabet in the upper and lower portions of the keypad, makes it difficult for users to input characters because it differs from a Korean word structure in which a consonant of Korean alphabet is located at a left side and a vowel of Korean alphabet is located at a right side.

Meanwhile, in a conventional mobile terminal, a keypad is fixed. Accordingly, maneuverability of key inputting is restricted by a shape of a terminal.

Furthermore, the keypad layout for right-handed users makes it inconvenient for left-handed users.

### SUMMARY OF THE INVENTION

The present invention is directed to implementation of a mobile terminal with a keypad which is attachable/detachable, arranged in 4 columns and 5 rows, and devised so that users can input characters using several fingers of one hand by adding a character string to a keypad of a conventional mobile terminal.

One aspect of the present invention is to provide a mobile terminal comprising a keypad, the keypad comprising a character part including a consonant part for inputting consonants of Korean alphabet, a right-side vowel part for inputting right-side vowels of Korean alphabet, a bottom vowel part for inputting bottom vowels of Korean alphabet, and a function control part, wherein the same character keys of a first character part having the consonant part located at an upper left portion of the keypad and a second character part having the consonant part located at an upper right portion share the same switch.

Another aspect of the present invention is to provide a mobile terminal comprising a keypad comprising a character part including a consonant part for inputting consonants of Korean alphabet, a right-side vowel part for inputting right-side vowels of Korean alphabet, a bottom vowel part for inputting bottom vowels of Korean alphabet, and a function control part; an attachment/detachment button for attaching or detaching the keypad to or from the mobile terminal; a wired communication unit for establishing a data communication path between the keypad and the mobile terminal; and a wireless communication unit for establishing a data communication path between the keypad and the mobile terminal.

Yet another aspect of the present invention is to provide a mobile terminal comprising a keypad comprising a character part including a consonant part for inputting consonants of Korean alphabet, a right-side vowel part for inputting right-side vowels of Korean alphabet, a bottom vowel part for inputting bottom vowels of Korean alphabet, and a function control part, wherein the same character keys of a first character part having the consonant part located at an upper left portion of the keypad and a second character part having the consonant part located at an upper right portion share the same switch; an attachment/detachment button for attaching or detaching the keypad to or from the mobile terminal; a wired communication unit for establishing a data communication path between the keypad and the mobile terminal; and a wireless communication unit for establishing a data communication path between the keypad and the mobile terminal.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1 illustrates the layout of a Korean alphabet keypad of a conventional mobile terminal;

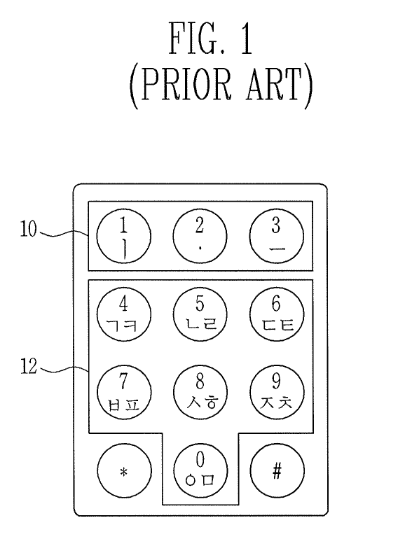

FIG. 2 illustrates a keypad according to an exemplary embodiment of the present invention;

FIGS. 3A and 3B illustrate processes in which a keypad is attached to and detached from a mobile terminal according to the present invention;

FIG. 4 is a block diagram illustrating the configuration of a keypad of a mobile terminal according to the present invention; and

FIG. 5 is a side view illustrating a switch for a keypad according to the present invention.

### DETAILED DESCRIPTION OF EMBODIMENTS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

In the present invention, a keypad of a mobile terminal includes an increased number of keys to simplify key input in one stroke or two strokes, and a Korean-consonant part, a right-side vowel part, and a bottom vowel part are located based on a composing principle of Korean word.

A mobile terminal such as a personal digital assistant (PDA), a smart phone, a digital multimedia broadcasting (DMB) phone, or an entertainment-based intelligent terminal such as a game-dedicated mobile phone requires an appropriate screen size. Accordingly, even though devices get thinner, the width thereof is kept constant. This implies a possibility that a character string can be added to an existing key layout comprised of 3 columns and 4 rows without significantly changing the size of a mobile terminal.

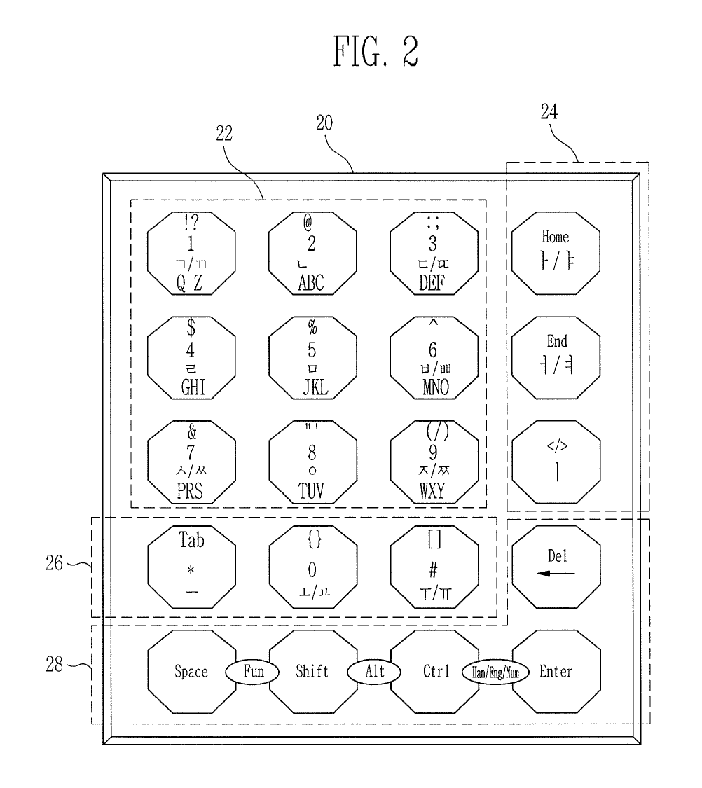

FIG. 2 illustrates a keypad according to an exemplary embodiment of the present invention.

Referring to FIG. 2, a keypad 20 includes a character part which includes a consonant part 22 generating consonants of Korean alphabet, a right-side vowel part 24 indicating right-side vowels of Korean alphabet, a bottom vowel part 26 indicating bottom vowels of Korean alphabet, and a function control part 28.

Specifically, the keypad 20 is comprised of 20 keys in 4 columns and 5 rows, in which a key layout of 3 columns and 3 rows located at the upper left of the keypad 20 constitutes the consonant part 22, a key layout of 1 column and 3 rows located at the right of the consonant part 22 constitutes the right-side vowel part 24, a key layout of 3 columns and 1 row located below the consonant part 22 constitutes the bottom vowel part 26, and other five keys constitute the function control part 28 for controlling key inputs or inputting, for example, a blank.

In this manner, the keys in the keypad are arranged in a more intuitive method by arranging the right-side vowel part 24 including [symbol] and the bottom vowel part 26 including [symbol] around the consonant part 22, similar to the arrangement of Korean consonants and vowels.

The consonant part 22 includes nine keys respectively labeled [symbol] arranged in 3 columns and 3 rows so that they are input in one stroke, and double consonants of Korean alphabet [symbol] arranged to be input by pressing keys labeled [symbol] twice successively. Although [symbol] are not directly labeled on the keypad, they can be input by pressing [symbol] together with a Shift key in the function control part 28.

In the right-side vowel part 24, vowels of Korean alphabet [symbol] are arranged in 1 column and 3 rows so that they are input in one stroke, and vowels of Korean alphabet [symbol] are arranged to be input by pressing the respective [symbol] twice successively. Alternatively, the vowels of Korean alphabet [symbol] may be arranged to be input by pressing [symbol] together with the Shift key in the function control part 28.

In the bottom vowel part 26, [symbol] are arranged in 3 columns and 1 row so that they are input in one stroke, and vowels of Korean alphabet [symbol] are arranged to be input by pressing [symbol] twice successively. Alternatively, the vowels of Korean alphabet [symbol] may be arranged to be input by pressing [symbol] together with the Shift key in the function control part 28.

The function control part 28 includes a key (Del, Backspace) for deleting, an Enter key for sentence input completion, a space key for inputting a space between characters, a Shift key for selecting optional characters, a Ctrl key for activating a particular function in combination with other keys, a Korean/English/Number select key for selecting one of Korean, English and numbers labeled on the same key, and an Alt key for activating a particular function in combination with other keys. The function control part 28 may further include a spare key (Fun) prepared for future additional functions.

The Space key and Enter key frequently used in inputting characters are located at a lower left end and a lower right end so that they are easily input using a thumb and a little finger, respectively, as shown in FIG. 2.

An attachment/detachment function of the keypad to or from the mobile terminal, which is another feature of the present invention, will now be described. The function is for assuring ambidextrous key input maneuverability, as described above.

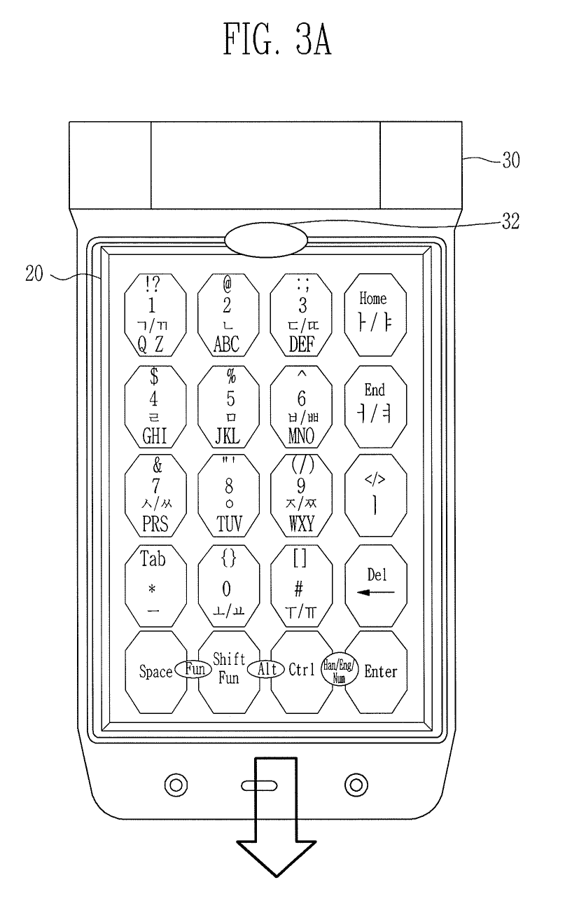

FIGS. 3A and 3B illustrate processes in which a keypad is attached to and detached from a mobile terminal according to the present invention.

Referring to FIG. 3A, a mobile terminal 30, a keypad 20, and a attachment/detachment button 32 for attaching or detaching a keypad 20 to or from the mobile terminal 30 are shown.

Through the attachment/detachment button 32, the keypad is detached from mobile terminal 30 in a direction indicated by an arrow.

The attachment/detachment button 32 may be operated to mechanically fix the keypad 20 to the mobile terminal 30 and may establish or block a power transfer path or a wired communication path between the keypad 20 and the mobile terminal 30 through current terminals.

For such attachment and detachment, data communication between the keypad 20 and the mobile terminal must be possible even when the keypad 20 is detached from the mobile terminal, and the keypad 20 needs to have a separate power supply capable of supplying power thereto.

The configuration of the keypad 20 that can be attached to and detached from the mobile terminal will be described.

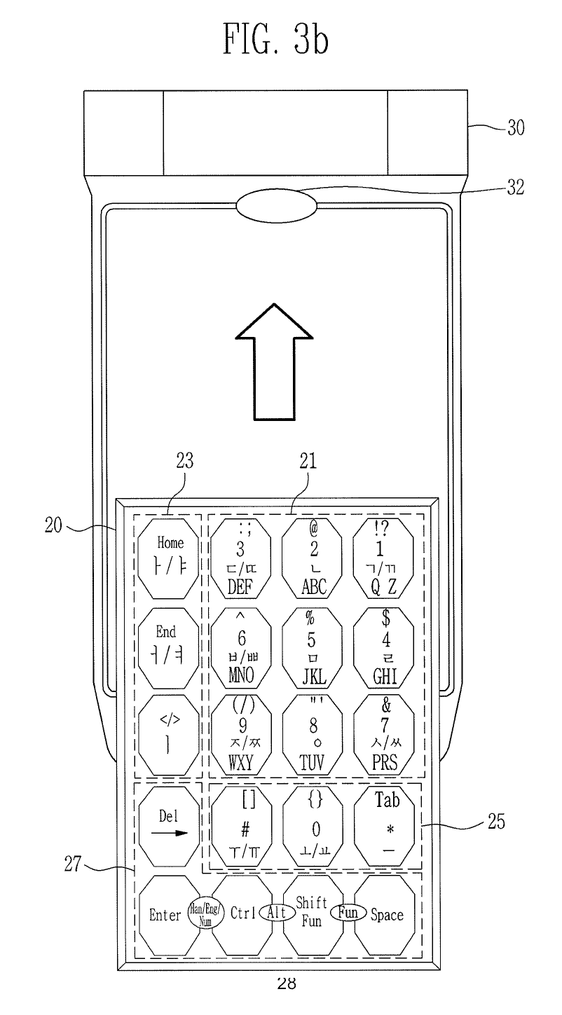

FIG. 4 is a block diagram illustrating the configuration of the keypad 20 according to the present invention.

Referring to FIG. 4, the keypad 20 includes a keypad input unit 41, a communication selecting unit 42, a first wired communication unit 43, a first wireless communication unit 44, and a power supply 45.

The keypad input unit 41 converts a signal input through each key of the keypad 20 into data to be sent to the mobile terminal.

The communication selecting unit 42 automatically re-establishes a data communication path according to whether the keypad 20 is attached to or detached from the mobile terminal 30. When the keypad 20 is attached to the mobile terminal 30, the communication selecting unit 42 establishes a wired communication path to the first wired communication unit 43 between the keypad 20 and the mobile terminal 30. However, when the keypad 20 is detached from the mobile terminal 30, the communication selecting unit 42 establishes a wireless communication path to the first wireless communication unit 44 between the keypad 20 and the mobile terminal 30.

The first wired communication unit 43 establishes a wired data communication path with the mobile terminal 30 in the keypad 20 for data transmission and reception. The first wireless communication unit 44 establishes a wireless data communication path with the mobile terminal 30 in the keypad 20 for data transmission and reception.

Although not shown in FIG. 4, the mobile terminal includes a second wired communication unit and a second wireless communication unit in its body for communication with the first wired communication unit 43 and the first wireless communication unit 44 of the keypad.

The second wired communication unit establishes a wired data communication path with the keypad 20 in the mobile terminal 30 for data transmission and reception. The second wireless communication unit establishes a wireless data communication path with the keypad 20 in the mobile terminal 30 for data transmission and reception.

Preferably, the first and second wireless communication units establish the wireless communication path between the keypad 20 and the mobile terminal 30 using communications protocols such as, Bluetooth or ZigBee.

Meanwhile, the power supply 45 in the keypad 20 operates differently according to whether the keypad 20 is attached to or detached from the mobile terminal. When the keypad 20 is attached to the mobile terminal, the power supply 45 stops supplying power to each unit in the keypad 20 and establishes a power transfer path so that power is charged in the power supply 45. However, when the keypad 20 is detached from the mobile terminal, the power supply 45 supplies the charged power to each unit in the keypad 20.

With the above-described configuration, the keypad 20 can be attached to and detached from the mobile terminal.

Referring back to FIG. 3B, a process in which the detached keypad 20 is attached back to the mobile terminal is shown. It can be seen from FIG. 3B that a key layout of the keypad 20 differs from that of FIG. 3A.

Unlike the key layout previously described in FIG. 2, the consonant part 21 is located at an upper right portion of the keypad, with keys arranged to begin with an upper right end, the right-side vowel part 23 is located at an upper left portion, and the bottom vowel part 25 is located at a right intermediate portion, so that a left-handed person can conveniently input keys. A function control part 27 is located at a lower portion, with keys arranged to begin on the right side.

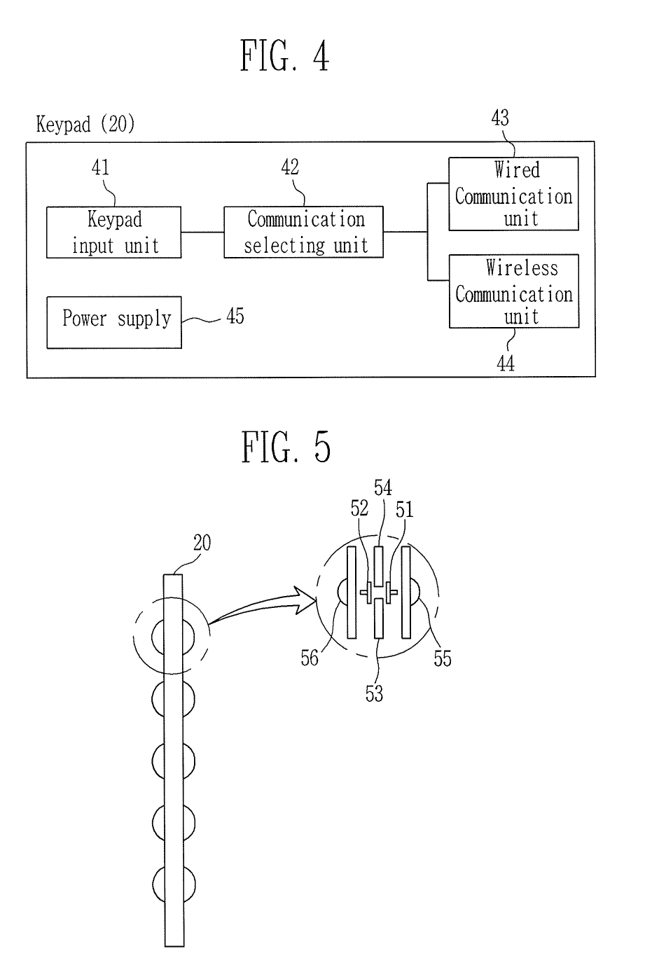

Meanwhile, such a configuration can be implemented without causing a significant change in the circuit of the keypad for a right-handed person of FIG. 3A. That is, the first character part having the consonant part located at an upper left portion of the keypad and the second character part having the consonant part located at an upper right portion are formed, and the same character keys of the character parts are disposed to share the same switch. A configuration in which keys of the first character part and keys of the second character part share the same switch will be described with reference to FIG. 5.

FIG. 5 is a side view illustrating a switch for a keypad according to the present invention.

Referring to FIG. 5, push buttons 51 and 52 operated upon pressing their corresponding key, conductors 53 and 54 interconnected by operation of each push button, and first and second character parts 55 and 56 are shown.

Each of the first and second character parts 55 and 56 has the same character labeled thereon and is pressed so that a corresponding one of the push buttons 51 and 52 connects between the disconnected conductors 53 and 54 and a corresponding key signal is input.

In summary, the first and second character parts 55 and 56 share the same switch and the keypad is detachably connected to the mobile terminal, thereby allowing both a right-handed person and a left-handed person to conveniently input key signals.

With the particular key layout of the keypad for a mobile terminal according to the present invention, users can input characters quickly and exactly and character input maneuverability can increase since the keypad can be attached to and detached from a mobile terminal. In addition, since the keypad includes the first and second character parts sharing the same switch, both a left-handed person and a right-handed person can freely input keys.

While the invention has been shown and described with reference to certain exemplary embodiments thereof, it will be understood by those skilled in the art that various changes in forms and details may be made therein without departing from the spirit and scope of the invention as defined by the appended claims.

What is claimed is:

1. A mobile terminal comprising a keypad, the keypad comprising:
a character part including a consonant part for inputting consonants of Korean alphabet, a right-side vowel part for inputting right-side vowels of Korean alphabet, a bottom vowel part for inputting bottom vowels of Korean alphabet, and a function control part,
wherein the same character keys of a first character part having the consonant part located at an upper left portion of the keypad and a second character part having the consonant part located at an upper right portion share the same switch.

2. The mobile terminal of claim 1, wherein the consonant part of the keypad has a key layout comprised of 3 columns and 3 rows, the right-side vowel part has a key layout comprised of 1 column and 3 rows, the bottom vowel part has a key layout comprised of 3 columns and 1 row, and the character part has a key layout comprised of 4 columns and 5 rows.

3. The mobile terminal of claim 1, wherein the first character part of the keypad comprises the right-side vowel part located at the right of the consonant part, and the bottom vowel part located below the consonant part, and
the second character part of the keypad comprises the right-side vowel part located at the left of the consonant part, and the bottom vowel part located below the consonant part.

4. The mobile terminal of claim 1, wherein the function control part of the keypad comprises:
a key for deleting input characters;
an Enter key for indicating that sentence input is completed;
a space key for inputting a space between characters;
a Shift key for allowing other characters labeled on each key to be selected and input; and
a Ctrl key for activating a particular function in combination with other keys.

5. The mobile terminal of claim 1, wherein the function control part of the keypad comprises:
a Korean/English/Number select key for selecting one of Korean, English and numbers labeled on the same key; and
an Alt key for activating a particular function in combination with other keys.

6. The mobile terminal of claim 1, wherein the function control part of the keypad comprises a spare key prepared for function addition.

7. A mobile terminal comprising:
a keypad comprising a character part including a consonant part for inputting consonants of Korean alphabet, a right-side vowel part for inputting right-side vowels of Korean alphabet, a bottom vowel part for inputting bottom vowels of Korean alphabet, and a function control part;
an attachment/detachment button for attaching or detaching the keypad to or from the mobile terminal;
a wired communication unit for establishing a data communication path between the keypad and the mobile terminal; and
a wireless communication unit for establishing a data communication path between the keypad and the mobile terminal.

8. The mobile terminal of claim 7, wherein the keypad further comprises a communication selecting unit for re-establishing the data communication path according to whether the keypad is attached to or detached from the mobile terminal.

9. The mobile terminal of claim 7, wherein the keypad further comprises a power supply for re-establishing a power charging or discharging path according to whether the keypad is attached to or detached from the mobile terminal.

10. The mobile terminal of claim 7, wherein the wired communication unit comprises:
a first wired communication unit for establishing a data communication path with the mobile terminal in the keypad for data transmission and reception; and
a second wired communication unit for establishing a data communication path with the keypad in the mobile terminal for data transmission and reception.

11. The mobile terminal of claim 7, wherein the wireless communication unit comprises:
a first wireless communication unit for establishing a data communication path with the mobile terminal in the keypad for data transmission and reception; and
a second wireless communication unit for establishing a data communication path with the keypad in the mobile terminal for data transmission and reception.

12. The mobile terminal of claim 7, wherein the wireless communication unit uses Bluetooth or ZigBee as protocol.

13. A mobile terminal comprising:
a keypad including a character part including a consonant part for inputting consonants of Korean alphabet, a right-side vowel part for inputting right-side vowels of Korean alphabet, a bottom vowel part for inputting bottom vowels of Korean alphabet, and a function control part, wherein the same character keys of a first character part having the consonant part located at an upper left portion of the keypad and a second character part having the consonant part located at an upper right portion share the same switch;
an attachment/detachment button for attaching or detaching the keypad to or from the mobile terminal;
a wired communication unit for establishing a data communication path between the keypad and the mobile terminal; and
a wireless communication unit for establishing a data communication path between the keypad and the mobile terminal.

14. The mobile terminal of claim 13, wherein the consonant part of the keypad has a key layout comprised of 3 columns and 3 rows, the right-side vowel part has a key layout comprised of 1 column and 3 rows, the bottom vowel part has a key layout comprised of 3 columns and 1 row, and the character part has a key layout comprised of 4 columns and 5 rows.

15. The mobile terminal of claim 13, wherein the first character part of the keypad comprises the right-side vowel part located at the right of the consonant part, and the bottom vowel part located below the consonant part, and
the second character part of the keypad comprises the right-side vowel part located at the left of the consonant part, and the bottom vowel part located below the consonant part.

16. The mobile terminal of claim 13, wherein the function control part of the keypad comprises:
a key for deleting input characters;
an Enter key for indicating that sentence input is completed;
a space key for inputting a space between characters;
a Shift key for allowing the other characters labeled on each key to be selected and input;
a Ctrl key for activating a particular function in combination with other keys.
a Hangul/English/Number select key for selecting one of Hangul, English and numbers labeled on the same key;
an Alt key for activating a particular function in combination with other keys; and
a spare key prepared for function addition.

17. The mobile terminal of claim 13, wherein the keypad further comprises a communication selecting unit for re-establishing the data communication path according to whether the keypad is attached to or detached from the mobile terminal; and
a power supply for re-establishing a power charging or discharging path according to whether the keypad is attached to or detached from the mobile terminal.

18. The mobile terminal of claim 13, wherein the wired communication unit comprises:
a first wired communication unit for establishing a data communication path with the mobile terminal in the keypad for data transmission and reception; and
a second wired communication unit for establishing a data communication path with the keypad in the mobile terminal for data transmission and reception.

19. The mobile terminal of claim 13, wherein the wireless communication unit comprises:
a first wireless communication unit for establishing a data communication path with the mobile terminal in the keypad for data transmission and reception; and
a second wireless communication unit for establishing a data communication path with the keypad in the mobile terminal for data transmission and reception.

20. The mobile terminal of claim 13, wherein the wireless communication unit uses Bluetooth or ZigBee as protocol.
